(19) United States
(12) Patent Application Publication
(10) Pub. No.: US 2012/0161197 A1
(43) Pub. Date: Jun. 28, 2012

(54) FLEXIBLE ORGANIC LIGHT-EMITTING DISPLAY DEVICE AND METHOD OF MANUFACTURING THE SAME

(75) Inventors: Choong-Youl Im, Yongin-city (KR); Il-Jeong Lee, Yongin-city (KR); Do-Hyun Kwon, Yongin-city (KR); Ju-Won Yoon, Yongin-city (KR); Sung-Eun Lee, Yongin-city (KR); Min-Woo Woo, Yongin-city (KR)

(73) Assignee: SAMSUNG MOBILE DISPLAY CO., LTD., Yongin-city (KR)

(21) Appl. No.: 13/242,211

(22) Filed: Sep. 23, 2011

(30) Foreign Application Priority Data
Dec. 23, 2010 (KR) 10-2010-0133711

(51) Int. Cl. H01L 27/15; H01L 33/42; B82Y 20/00

(52) U.S. Cl. 257/100; 438/23; 977/952; 257/E27.12; 257/E33.064

(57) ABSTRACT

A flexible organic light-emitting display device has a thin film encapsulation structure. The flexible organic light-emitting display device can be manufactured by a method including sequentially stacking a glass substrate, a first flexible substrate in which conductive particles are integrally dispersed, a display unit comprising a thin film transistor (TFT) layer and a light-emitting layer, and a second flexible substrate. The glass substrate can then be separated from the first flexible substrate by emitting light.

### CROSS-REFERENCE TO RELATED APPLICATIONS

This application claims the benefit of Korean Patent Application No. 10-2010-0133711, filed on Dec. 23, 2010, in the Korean Intellectual Property Office, the disclosure of which is incorporated herein in its entirety by reference.

### BACKGROUND

1. Field

The present disclosure relates to a flexible organic light-emitting display device using a thin film encapsulation structure for preventing penetration of moisture, and a method of manufacturing the flexible light-emitting display device.

2. Description of the Related Technology

Many studies have been conducted on organic light-emitting display devices because organic light-emitting display devices may be made thin and flexible due to their driving characteristics.

A display unit of such an organic light-emitting display device may be deteriorated due to penetration of moisture in some instances. Accordingly, the organic light-emitting display device would benefit from an encapsulation structure for sealing and protecting the display unit from moisture.

Generally, an encapsulation substrate formed of a glass material is put on a glass substrate on which a display unit is formed and a sealant is used to seal the glass substrate and the encapsulation substrate together. Typically, a sealant, such as an ultraviolet (UV)-curable agent, is applied around the display unit of the glass substrate, the encapsulation substrate is put on the glass substrate to cover the glass substrate, and UV rays are emitted to cure the sealant, to achieve a sealed state.

However, such encapsulation structures may not be flexible. Flexible organic light-emitting display devices are desired, which have high enough flexibility to be installed while being bent. If the glass substrate and the encapsulation substrate each formed of a hard material are used as in the conventional encapsulation structure, such requirements may not be met.

A thin film encapsulation structure using a thin film layer formed of a polymer or the like, instead of a substrate formed of a glass material, has been suggested. In such thin film encapsulation structures, appropriate thin film layers are formed on a glass substrate and on an encapsulation substrate, the thin film layers are adhered to each other, and the glass substrate and the encapsulation substrate are separated, to achieve a sealed state by using the soft thin film layers instead of the glass substrate and the encapsulation substrate.

However, in such structures, when the glass substrate and the encapsulation substrate are removed from the thin film layers in order to form the thin film encapsulation structure, static electricity greater than several kV may be produced on an interface between the glass substrate and the encapsulation substrate. The display unit in the thin film encapsulation structure may be damaged due to the static electricity thus formed.

### SUMMARY OF CERTAIN INVENTIVE ASPECTS

The present disclosure provides a flexible organic light-emitting display device which has a soft thin film encapsulation structure to reduce the risk of damage to a display unit due to static electricity produced during a manufacturing process, and a method of manufacturing the flexible organic light-emitting display device.

According to one aspect, there is provided a flexible organic light-emitting display device including: a first flexible substrate; a display unit formed on the first flexible substrate and comprising a thin film transistor (TFT) layer and a light-emitting layer; and a second flexible substrate formed on the display unit, wherein conductive particles are integrally dispersed in the first flexible substrate.

The conductive particles may include at least one of indium tin oxide (ITO) nanoparticles and silver (Ag) nanoparticles.

The first flexible substrate may include a first polymer layer and a first barrier layer which are sequentially stacked, the second flexible substrate may include a second barrier layer and a second polymer layer which are sequentially stacked, and the conductive particles may be dispersed in the first polymer layer.

The first polymer layer may have a glass transition temperature of about 500° C. or higher.

The second polymer layer may have a glass transition temperature of about 350° C. or higher.

A thickness of each of the first polymer later and the second polymer layer may range from about 1 to about 10 μm.

Each of the first barrier layer and the second barrier layer may include a SiO/SiN multi-layered film.

A water vapor transmission rate of each of the first barrier layer and the second barrier layer may be equal to or lower than about 10⁻⁵ g/m²·day.

According to another aspect, there is provided a method of manufacturing a flexible organic light-emitting display device, the method including: sequentially stacking a glass substrate, a first flexible substrate in which conductive particles are integrally dispersed, a display unit comprising a TFT layer and a light-emitting layer, and a second flexible substrate; and separating the glass substrate from the first flexible substrate by emitting light.

The conductive particles may include at least one of ITO nanoparticles and Ag nanoparticles.

The first flexible substrate may include a first polymer layer and a first barrier layer which are sequentially stacked, the second flexible substrate may include a second barrier layer and a second polymer layer which are sequentially stacked, and the conductive particles may be dispersed in the first polymer layer.

The first polymer layer may have a glass transition temperature of about 500° C. or higher.

The second polymer layer may be a transparent layer having a glass transition temperature of about 350° C. or higher.

A thickness of each of the first polymer layer and the second polymer layer may range from about 1 to about 10 μm.

Each of the first barrier layer and the second barrier layer may include a SiO/SiN multi-layered film.

A water vapor transmission rate of each of the first barrier layer and the second barrier layer may be equal to or lower than about 10⁻⁵ g/m²·day.

### BRIEF DESCRIPTION OF THE DRAWINGS

The above and other features and advantages will become more apparent by describing in detail certain embodiments with reference to the attached drawings in which:

FIG. 1 is a cross-sectional view illustrating an embodiment of a flexible organic light-emitting display device;

FIGS. 2A through 2C are cross-sectional views illustrating an embodiment of a method of manufacturing the flexible organic light-emitting display device of FIG. 1; and

FIG. 3 is a cross-sectional view illustrating a first polymer layer of the flexible organic light-emitting display device of FIG. 1.

### DETAILED DESCRIPTION OF CERTAIN INVENTIVE EMBODIMENTS

Certain embodiments will now be described more fully with reference to the accompanying drawings.

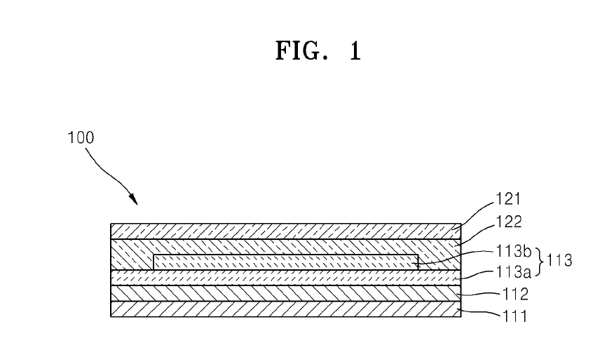

FIG. 1 is a cross-sectional view illustrating an embodiment of a flexible organic light-emitting display device 100, which is a top-emission type device.

As shown in FIG. 1, the flexible organic light-emitting display device 100 includes a first flexible substrate including a first polymer layer 111 and a first barrier layer 112, a display unit 113 including a thin film transistor (TFT) layer 113a and a light-emitting layer 113b, and a second flexible substrate including a second barrier layer 122 and a second polymer layer 121, which are sequentially stacked. In some embodiments, an encapsulation structure is configured such that the display unit 113 is sealed by the first and second flexible substrates including the first and second polymer layers 111 and 121 and the first and second barrier layers 112 and 122 instead of conventional glass substrates.

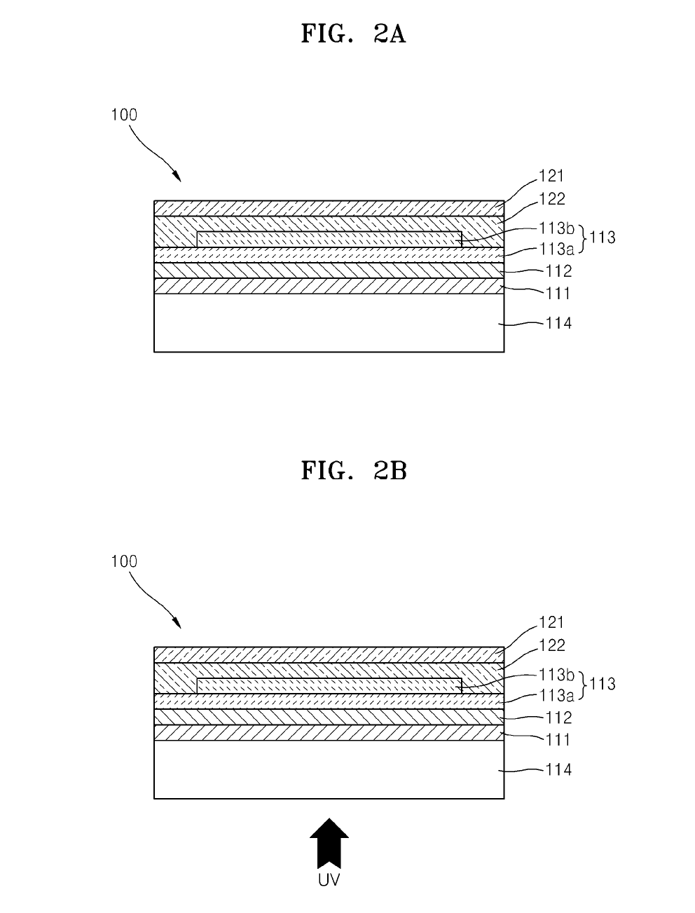

The first polymer layer 111 can be formed of heat-resistive polyimide having a glass transition temperature of about 500° C. or higher, and it may be formed by polymerization of BPDA-biphenyl-tetracarboxylic acid dianhydride (3,3′,4,4′-Biphenyl tetracarboxylic Dianhydride) and p-phenylenediamine (PDA). Since the display unit 113 is stacked on the first polymer layer 111 and exposure for patterning is performed several times, it is preferable that the first polymer 111 be formed of a material having high heat resistance in order to prevent deterioration. The first polymer layer 111 may be formed by spin coating on a glass substrate 114 (see FIG. 2A), or may be attached as an adhesive film to the glass substrate 114. A thickness of the first polymer layer 111 may range from about 1 to about 10 μm. The glass substrate 114 is separated from the first polymer layer 111 during a subsequent process. Since the first polymer layer 111 of the first flexible substrate is a lower substrate that replaces a conventional glass substrate, a very flexible thin film substrate having a thickness of about 1 to about 10 μm is achieved.

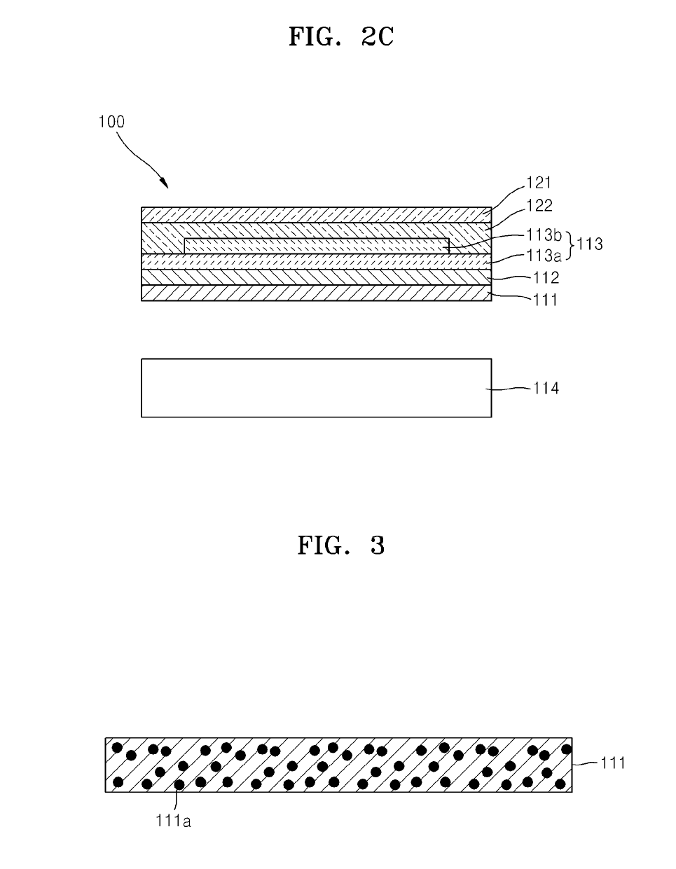

As shown in FIG. 3, conductive particles 111a are dispersed in the first polymer layer 111, in order to prevent static electricity from being produced on an interface between the first polymer layer 111 and the glass substrate 114 when the glass substrate 114 is separated by using laser. Due to the conductive particles 111a, static electricity is prevented from being accumulated around the interface, thereby preventing static electricity accumulated on the interface between the first polymer layer 111 and the glass substrate 114 from being discharged all at once, and preventing an electric shock, which may be greater than several kV, from being applied to the display unit 113. In various embodiments, the conductive particles 111a may be indium tin oxide (ITO) nanoparticles, silver (Ag) nanoparticles, or the like. The conductive particles 111a may be dispersed in a coating solution for the spin coating, or may be dispersed in the adhesive film.

In some embodiments, the first barrier layer 112 stacked on the first polymer layer 111 having moisture resistance for preventing penetration of moisture may be, a SiO/SiN multi-layered film in which SiO and SiN are stacked as multi-layers. The first barrier layer 112 has excellent moisture resistance. A water vapor transmission rate of the first barrier layer 112 may be equal to or lower than about 10⁻⁵ g/m²·day. The first barrier layer 112 may be deposited on the first polymer layer 111.

Since the display unit 113, and in particular, the light-emitting layer 113b of the display unit 113, may be vulnerable to moisture, it is desirable to firmly seal the display unit 113 from moisture.

The second barrier layer 122 of the second flexible substrate formed on the display unit 113 may have moisture resistance for preventing penetration of moisture and may be, in some embodiments, a SiO/SiN multi-layered film in which SiO and SiN are stacked as multi-layers. A water vapor transmission rate of the second barrier layer 122 may be equal to or lower than about 10⁻⁵ g/m²·day.

The second polymer layer 121 formed on the second barrier layer 122 may be formed of transparent polyimide having a glass transition temperature of about 350° C. or higher. The transparent polyimide may be a polymer composed of one or more of a dianhydride monomer, a diamine monomer, and an amide monomer.

In some embodiments, the transparent polyimide is a polymer composed of a dianhydride monomer and a diamine monomer, or a polymer composed of a dianhydride monomer and an amide monomer. In some embodiments, the dianhydride monomer may include pyromellitic dianhydride (PMDA), and 1,2,3,4-cyclobutanetetracarboxylic dianhydride (CBDA). In some embodiments, the diamine monomer may include trans-1,4-cyclohexanediamine (CHDA). In some embodiments, the amide monomer may include hexamethylphosphoramide (HMPA).

In embodiments where the flexible organic light-emitting display device is a top-emission type, an image created by the display unit 113 may be viewed at the second polymer layer side. Accordingly, the second polymer layer 121 can be a transparent layer that transmits the image created by the display unit 113. If the second polymer layer 121 is formed of a transparent polymer, heat resistance of the second polymer layer 121 is slightly lower than that of the first polymer layer 111 that is not formed of a transparent polymer. However, the second polymer layer 121 is not subjected to patterning when the display unit 13 is patterned. When the glass substrate 114 is separated at a later stage, since UV exposure is performed, in order to prevent any problem on the second polymer layer 121, the second polymer layer 121 has a glass transition temperature of about 350° C. or higher. Although the second polymer layer 121 has lower heat resistance than that of the first polymer layer 111, the second polymer layer 121 may withstand a high temperature of about 350° C.

A thickness of the second polymer layer 121 may be about 1 to about 10 μm. Since the second polymer layer 121 becomes an upper substrate that replaces a conventional glass substrate, a very flexible thin film substrate having a thickness of about 1 to about 10 μm is achieved.

In some embodiments, the flexible organic light-emitting display device 100 constructed as described above may be manufactured by the following method.

FIGS. 2A through 2C are cross-sectional views illustrating an embodiment of a method of manufacturing the flexible organic light-emitting display device 100 of FIG. 1. Referring to FIG. 2A, the glass substrate 114 is prepared, and thin film layers are formed on the glass substrate 114.

The first flexible substrate, or the first polymer layer 111 in which the plurality of conductive particles 111a (see FIG. 3A) are dispersed, and the first barrier layer 112 having moisture resistance are sequentially formed on the glass substrate 114. Then the display unit 113, including the TFT layer 113a and the light-emitting layer 113b, is patterned.

The second barrier layer 122 and the second polymer layer 121 of the second flexible substrate are sequentially formed on the display unit 113.

Alternatively, the first and second polymer layers 111 and 121 may be attached as adhesive films.

Next, referring to FIG. 2B, UV laser is emitted over an entire surface of the glass substrate 114. The glass substrate 114 and the first polymer layer 111 are separated from each other due to a high difference in thermal expansion coefficients between the glass substrate 114 and the first polymer layer 111.

Referring to FIG. 2C, the glass substrate 114 is separated, and the first polymer layer 111 is left as a lower substrate. Conventionally, when laser is emitted to separate the first glass substrate 114, static electricity accumulated on an interface between the glass substrate 114 and the first polymer layer 111 is discharged from the interface, thereby causing damage to the display unit 113. However, in embodiments disclosed herein, since the conductive particles 111a dispersed in the first polymer layer 111 do not allow static electricity from being accumulated on the interface, such a damage can be avoided.

As a result, an encapsulation structure for sealing the display unit 113 is defined by the first flexible substrates including thin films, the first and second polymer layers 111 and 121 and the first and second barrier layers 112 and 122.

Hence, since the first and second polymer layers 111 and 121 which are thin films replace a glass substrate which is hard and thick, the flexible organic light-emitting display device 100 can be soft. Also, since the first and second barrier layers 112 and 122, which are SiO/SiN multi-layered films, have a water vapor transmission rate of equal to or lower than about 10⁻⁵ g/m²·day, excellent moisture resistance may be ensured.

Furthermore, due to the conductive particles 111a, since static electricity is prevented from being produced when the glass substrate 114 is separated, damage to the display unit 113 due to an electric shock may be prevented.

As described above, since the flexible organic light-emitting display device and the method of manufacturing the same according to the present invention has a thin film encapsulation structure, softness of the flexible organic light-emitting display device is greatly improved. Since the flexible organic light-emitting display device and the method of manufacturing the same prevent static electricity from being produced during a manufacturing process, the risk of damage to the flexible organic light-emitting display device is greatly reduced.

While the present invention has been particularly shown and described with reference to certain embodiments thereof, it will be understood by those of ordinary skill in the art that various changes in form and details may be made therein without departing from the spirit and scope of the present invention as defined by the following claims.

What is claimed is:

1. A flexible organic light-emitting display device comprising:
a first flexible substrate;
a display unit formed on the first flexible substrate and comprising a thin film transistor (TFT) layer and a light-emitting layer; and
a second flexible substrate formed on the display unit,
wherein conductive particles are integrally dispersed in the first flexible substrate.

2. The flexible organic light-emitting display device of claim 1, wherein the conductive particles comprise at least one of indium tin oxide (ITO) nanoparticles and silver (Ag) nanoparticles.

3. The flexible organic light-emitting display device of claim 1, wherein the first flexible substrate comprises a first polymer layer and a first barrier layer which are sequentially stacked, the second flexible substrate comprises a second barrier layer and a second polymer layer which are sequentially stacked, and wherein the conductive particles are dispersed in the first polymer layer.

4. The flexible organic light-emitting display device of claim 3, wherein the first polymer layer has a glass transition temperature of about 500° C. or higher.

5. The flexible organic light-emitting display device of claim 3, wherein the second polymer layer has a glass transition temperature of about 350° C. or higher.

6. The flexible organic light-emitting display device of claim 3, wherein a thickness of each of the first polymer later and the second polymer layer ranges from about 1 to about 10 μm.

7. The flexible organic light-emitting display device of claim 3, wherein each of the first barrier layer and the second barrier layer comprises a SiO/SiN multi-layered film.

8. The flexible organic light-emitting display device of claim 7, wherein a water vapor transmission rate of each of the first barrier layer and the second barrier layer is equal to or lower than about 10⁻⁵ g/m²·day.

9. A method of manufacturing a flexible organic light-emitting display device, the method comprising:
sequentially stacking a glass substrate, a first flexible substrate in which conductive particles are integrally dispersed, a display unit comprising a TFT layer and a light-emitting layer, and a second flexible substrate; and
separating the glass substrate from the first flexible substrate by emitting light.

10. The method of claim 9, wherein the conductive particles comprise at least one of ITO nanoparticles and Ag nanoparticles.

11. The method of claim 9, wherein the first flexible substrate comprises a first polymer layer and a first barrier layer which are sequentially stacked, the second flexible substrate comprises a second barrier layer and a second polymer layer which are sequentially stacked, and the conductive particles are dispersed in the first polymer layer.

12. The method of claim 11, wherein the first polymer layer has a glass transition temperature of about 500° C. or higher.

13. The method of claim 11, wherein the second polymer layer is a transparent layer having a glass transition temperature of about 350° C. or higher.

14. The method of claim 11, wherein a thickness of each of the first polymer layer and the second polymer layer ranges from about 1 to about 10 μm.

15. The method of claim 11, wherein each of the first barrier layer and the second barrier layer comprises a SiO/SiN multi-layered film.

16. The method of claim 15, wherein a water vapor transmission rate of each of the first barrier layer and the second barrier layer is equal to or lower than about 10⁻⁵ g/m²·day.
